(19) United States
(12) Patent Application Publication
(10) Pub. No.: US 2025/0248226 A1
(43) Pub. Date: Jul. 31, 2025

(54) OUT-GASSING HOLE INSIDE ACTIVE AREA TO IMPROVE AP RELIABILITY

(71) Applicant: Applied Materials, Inc., Santa Clara, CA (US)

(72) Inventor: Chung-Chia CHEN, Hsinchu City (TW)

(21) Appl. No.: 18/887,704

(22) Filed: Sep. 17, 2024

Related U.S. Application Data
(60) Provisional application No. 63/627,507, filed on Jan. 31, 2024.

(51) Int. Cl. H10K 59/122; H10K 59/12; H10K 59/35

(52) U.S. Cl. CPC H10K 59/122; H10K 59/1201; H10K 59/35

(57) ABSTRACT

The present disclosure provides devices, sub-pixels, and methods thereof. The sub-pixel includes a plurality of pixel structures separating a plurality of anodes. The plurality of pixel structures are disposed over a substrate. Each pixel structure of the plurality of pixel structures includes an outgassing hole. A plurality of overhang structures are disposed over the plurality of pixel structures. Each overhang structure of the plurality of overhang structures includes an upper portion disposed over a lower potion. A bottom surface of the upper portion extends laterally past an upper surface of the lower portion. The lower portion fills the outgassing hole. An organic light emitting diode (OLED) material is disposed over an upper surface of the plurality of anodes and an upper surface of the plurality of pixel structures. A cathode is disposed over the OLED material and the upper surface of the plurality of pixel structures.

### CROSS REFERENCE TO RELATED APPLICATIONS

This application claims priority to U.S. Provisional Patent Application No. 63/627,507, filed on Jan. 31, 2024, the entirety of which is incorporated herein by reference.

### BACKGROUND

### Field

Embodiments described herein generally relate to a display. More specifically, embodiments described herein relate to sub-pixel circuits and methods of forming sub-pixel circuits that may be utilized in a display such as an organic light-emitting diode (OLED) display.

### Description of the Related Art

Input devices including display devices may be used in a variety of electronic systems. An organic light-emitting diode (OLED) is a light-emitting diode (LED) in which the emissive electroluminescent layer is a film of an organic compound that emits light in response to an electric current. OLED devices are classified as bottom emission devices if light emitted passes through the transparent or semi-transparent bottom electrode and substrate on which the panel was manufactured. Top emission devices are classified based on whether or not the light emitted from the OLED device exits through the lid that is added following the fabrication of the device. OLEDs are used to create display devices in many electronics today. Today's electronics manufacturers are pushing these display devices to shrink in size while providing higher resolution than just a few years ago.

OLED pixel patterning is currently based on a process that restricts panel size, pixel resolution, and substrate size. Rather than utilizing a fine metal mask, photo lithography should be used to pattern pixels. Currently, OLED pixel patterning requires lifting off organic material after the patterning process. When lifted off, the organic material leaves behind a particle issue that disrupts OLED performance. Accordingly, what is needed in the art are sub-pixel circuits and methods of forming sub-pixel circuits to improve OLED performance.

### SUMMARY

In one embodiment, the present disclosure provides a sub-pixel. The sub-pixel includes a plurality of pixel structures separating a plurality of anodes. The plurality of pixel structures are disposed over a substrate. Each pixel structure of the plurality of pixel structures includes an outgassing hole. A plurality of overhang structures are disposed over the plurality of pixel structures. Each overhang structure of the plurality of overhang structures includes an upper portion disposed over a lower potion. A bottom surface of the upper portion extends laterally past an upper surface of the lower portion. The lower portion fills the outgassing hole. An organic light emitting diode (OLED) material is disposed over an upper surface of the plurality of anodes and an upper surface of the plurality of pixel structures. A cathode is disposed over the OLED material and the upper surface of the plurality of pixel structures.

In another embodiment, the present disclosure provides a device. The device includes a plurality of sub-pixels including at least a first sub-pixel, a second sub-pixel, and a third sub-pixel. The first sub-pixel, the second sub-pixel, and the third sub-pixel each include a plurality of pixel structures. The plurality of pixel structures separate a plurality of anodes. Each pixel structure of the plurality of pixel structures include an outgassing hole. Overhang structures are disposed over the plurality of pixel structures. Each overhang structure of the plurality of overhang structures includes an upper portion disposed over a lower potion. A bottom surface of the upper portion extends laterally past an upper surface of the lower portion. The lower portion fills the outgassing hole. An organic light emitting diode (OLED) material is disposed over an upper surface of the plurality of anodes and an upper surface of the plurality of pixel structures. A cathode is disposed over the OLED material and the upper surface of the plurality of pixel structures.

In another embodiment, the present disclosure provides methods of forming devices. The methods include depositing an anode and a pixel intermediate layer (PIL) over a substrate. Portions of the PIL are removed to form a plurality of pixel structures. An etch layer is deposited over a portion of the plurality of pixel structures. The plurality of pixel structures are etched to form an outgassing hole in the plurality of pixel structures. The outgassing hole exposes a surface of the substrate. The plurality of pixel structures, the anode, and the substrate are cured. Overhang structures are formed over the plurality of pixel structures. The overhang structures include an upper portion disposed over a lower portion. An organic light emitting diode (OLED) material, a cathode, and an encapsulation layer is deposited. A resist is deposited in a first sub-pixel and patterned. A portion of the OLED material, a portion of the cathode, and a portion of the encapsulation layer is removed. The resist is removed.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIGS. 1A-1B are schematic, cross-sectional view of a sub-pixel circuit according to embodiments.

FIG. 2 is a flow diagram of a method for forming a sub-pixel circuit according to embodiments.

FIGS. 3A-3L are schematic, cross-sectional views of a substrate during a method of forming a sub-pixel according to embodiments.

FIG. 4 is a flow diagram of a method for forming a sub-pixel circuit according to embodiments.

FIGS. 5A-5K are schematic, cross-sectional views of a substrate during a method of forming a sub-pixel according to embodiments.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein generally relate to a display. More specifically, embodiments described herein relate to sub-pixel circuits and methods of forming sub-pixel circuits that may be utilized in a display such as an organic light emitting diode (OLED) display. The sub-pixel circuits can include pixel structures, each has an outgassing hole thereby allowing moisture that is absorbed during fabrication processes to be released. The release of the absorbed moisture prevents pixel degradation and/or peeling, by reducing trapped moisture between the substrate and the anodes and/or pixel defining layers during sub-pixel circuit fabrication.

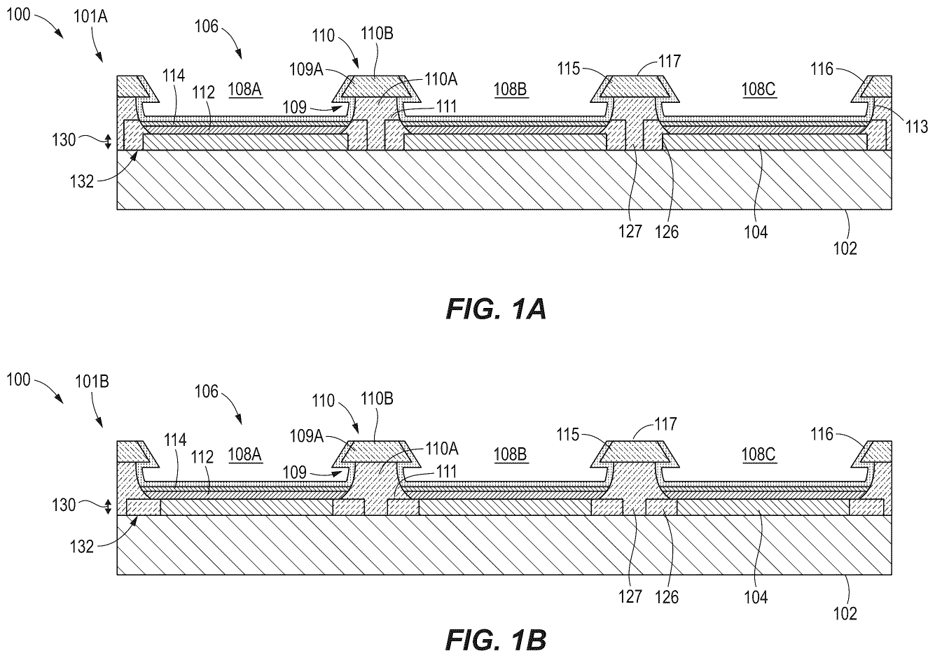

FIGS. 1A-1B are schematic, cross-sectional views of a sub-pixel circuit 100 according to embodiments. FIG. 1A includes a first pixel structure (PS) arrangement 101A. FIG. 1B includes a second PS arrangement 101B. The sub-pixel circuit 100 includes a substrate 102. Metal-containing layers 104 (e.g., anodes) may be patterned on the substrate 102 and are defined by adjacent PS disposed on and/or over the substrate 102. In one embodiment, the metal-containing layer 104 are pre-patterned over the substrate 102, e.g., the substrate 102 is pre-patterned with metal-containing layer 104 of indium tin oxide (ITO). The substrate 102 is backplane including one or more complementary metal-oxide-semiconductor (CMOS) or thin-film transistor (TFT) arrays. The metal-containing layer 104 are configured to operate as anodes of respective sub-pixels. In one embodiment, the metal-containing layer 104 is a layer stack of a first transparent conductive oxide (TCO) layer, a second metal-containing layer disposed on the first TCO layer, and a third TCO layer disposed on the second metal-containing layer. The metal-containing layer 104 include, but are not limited to, chromium, titanium, gold, silver, copper, aluminum, ITO, a combination thereof, or other suitably conductive materials.

The PS 126 are disposed over and/or on the substrate 102. The PS 126 include one of an organic material, an organic material with an inorganic coating disposed thereover, or an inorganic material. The organic material of the PS 126 includes, but is not limited to, polyimides. The inorganic material of the PS 126 includes, but is not limited to, silicon oxide (SiO₂), silicon nitride (Si₃N₄), silicon oxynitride (Si₂N₂O), magnesium fluoride (MgF₂), or combinations thereof. Adjacent PS define a respective sub-pixel and expose the metal-containing layer 104 of the sub-pixel circuit 100. The PS 126 includes outgassing holes 127. The outgassing holes 127 have a depth 130 from the upper surface 111 of the PS 126 to the topmost surface 132 of the substrate 102. The depth 130 can include a depth of about 0.1 μm to about 1.0 μm, e.g., about 0.1 μm to about 0.9 μ, about 0.2 μm to about 0.8 μm, or about 0.3 μm to about 0.7 μm. During further processing the material of the lower portion 110A of the overhang structures 110 are disposed in the outgassing holes 127, as described herein. In some embodiments, the outgassing holes 127 includes a diameter of about 0.1 μm to about 10 μm, e.g., about 0.1 μm to about 5 μm, about 0.5 μm to about 5 μm, or about 1 μm to about 5 μm. Without being bound by theory, the outgassing holes 127 can allow for out-gassing of moisture that is absorbed by the substrate 102, the PS 126, and/or the metal-containing layers 104, thereby reducing peeling and/or pixel degradation during fabrication processes.

The sub-pixel circuit 100 has a plurality of sub-pixels 106 including at least a first sub-pixel 108A, a second sub-pixel 108B, and a third sub-pixel 108C. While the Figures depict the first sub-pixel 108A, the second sub-pixel 108B, and the third sub-pixel 108C. The sub-pixel circuit 100 of the embodiments described herein may include three or more sub-pixels 106, such as a fourth and a fifth sub-pixel. Each sub-pixel 106 has OLED materials configured to emit a white, red, green, blue or other color light when energized, e.g., the OLED materials of the first sub-pixel line emits a red light when energized, the OLED materials of the second sub-pixel line emits a green light when energized, the OLED materials of the third sub-pixel line emits a blue light when energized, and the OLED materials of a fourth sub-pixel emits another color light when energized. The OLED materials may be configured to emit the same color light when energized, e.g., the OLED materials of the first sub-pixel 108A emit a red light when energized, the OLED materials of the second sub-pixel 108B emit a green light when energized, and the OLED materials of the third sub-pixel 108C emit a blue light when energized.

Each sub-pixel 106 includes adjacent overhangs 109. The overhang structures 110 are permanent to the sub-pixel circuit 100. Each overhang structure 110 includes adjacent overhangs 109. The adjacent overhangs 109 are defined by an overhang extension 109A of an upper portion 110B extending laterally past an upper surface of a lower portion 110A. The lower portion 110A is disposed on an upper surface 111 of the PS 126. In some embodiments, the lower portion 110A is disposed on and/or over an upper surface 111 of the PS 126 and a portion of the metal-containing layer 104.

In some embodiments, the lower portion 110A is a non-conductive inorganic material. The non-conductive materials of the lower portion 110A include an inorganic silicon-containing material, e.g., amorphous silicon (a-Si), silicon nitride (Si₃N₄), silicon oxide (SiO₂), silicon oxynitride (Si₂N₂O), or combinations thereof. In some embodiments, the lower portion 110A includes conductive materials. The conductive materials of the lower portion 110A include titanium (Ti), aluminum (Al), aluminum neodymium (AlNd), molybdenum (Mo), molybdenum tungsten (MoW), copper (Cu), or combinations thereof.

In some embodiments, the upper portion 110B is a conductive inorganic material. The conductive inorganic materials of the upper portion 110B include a metal-containing material, e.g., copper (Cu), chromium (Cr), aluminum (Al), aluminum neodymium (AlNd), molybdenum (Mo), molybdenum tungsten (MoW), titanium (Ti), or combinations thereof. In some embodiments, the upper portion 110B includes inorganic materials. The inorganic materials include silicon nitride (Si₃N₄), silicon oxide (SiO₂), silicon oxynitride (Si₂N₂O), or combinations thereof.

The adjacent overhangs 109 are defined by the overhang extension 109A. At least a bottom surface of the upper portion 110B is wider than the upper surface of the lower portion 110A to form the overhang extension 109A. The overhang extension 109A of the upper portion 110B forms the adjacent overhangs 109 and allows for the upper portion 110B to shadow the lower portion 110A. The shadowing of the adjacent overhangs 109 provides for evaporation deposition of an OLED material 112 and a cathode 114. The OLED material 112 may include one or more of a hole injection layer (HIL), a hole transport layer (HTL), an emissive layer (EML), an electron transport layer (ETL), and an electron injection layer (EIL). The OLED material 112 is disposed over and in contact with the metal-containing layer 104. The OLED material 112 is disposed under adjacent overhangs 109 and may contact a sidewall 113 of the lower portion 110A. In one embodiment, the OLED material 112 is different from the material of the lower portion 110A, the upper portion 110B, and the PS 126. The cathode 114 is disposed over the OLED material 112 and extends under the adjacent overhangs 109. The cathode 114 extends past an endpoint of the OLED material 112.

The cathode 114 is disposed over the OLED material 112 and/or the PS 126 in each sub-pixel 106. The cathode 114 may be disposed on a portion of a sidewall 113 of the lower portion 110A. In some embodiments, an assistant cathode may be disposed on an upper surface of the PS 126. The cathode 114 and the assistant cathode include a conductive material, such as a metal, e.g., silver, magnesium, chromium, titanium, aluminum, transparent conductive oxides, e.g., indium zinc oxide, indium tin oxide, or a combination thereof. In one embodiment, material of the cathode 114 is different from the material of the lower portion 110A or the upper portion 110B. In some embodiments the OLED material 112 and the cathode 114 are disposed over a sidewall 115 of the upper portion 110B of the overhang structures 110. In still other embodiments, the OLED material 112 and the cathode 114 end on the sidewall 113 of the lower portion 110A, e.g., are not disposed over the sidewall 115 of the upper portion 110B.

Each sub-pixel 106 includes an encapsulation layer 116. The encapsulation layer 116 may be or may correspond to a local passivation layer. The encapsulation layer 116 of a respective sub-pixel is disposed over the cathode 114 (and OLED material 112) with the encapsulation layer 116 extending under at least a portion of adjacent overhangs 109 and along a sidewall 113 of each of the lower portion 110A. In some embodiments, which can be combined with other embodiments described herein, the encapsulation layer 116 is disposed over the sidewall 115 of the upper portion 110B. In some embodiments, which can be combined with other embodiments described herein, the encapsulation layer 116 is disposed over the top surface 117 of the upper portion 110B of the overhang structures 110. The encapsulation layer 116 includes the non-conductive inorganic material, such as the silicon-containing material. The silicon-containing material may include Si₃N₄ containing materials. The encapsulation layer may be disposed over the cathode, in which the encapsulation layer may extend under at least a portion of the upper portion 110B past the cathode along the sidewall of the lower portion and contact a bottom surface of the upper portion of the overhang structures.

In some embodiments, one or more capping layers (not shown) are disposed between the cathode 114 and the encapsulation layer 116. The capping layers may include an organic material or an inorganic material. For example, the inorganic material can include lithium fluoride.

The first PS arrangement 101A and the second PS arrangement 101B of the sub-pixel circuit 100 further include at least a global passivation layer (not shown) disposed over the overhang structures 110 and the encapsulation layers 116. The global passivation layer can include a non-conductive inorganic material, such as the silicon-containing material. The silicon-containing material may include Si₃N₄ containing materials. An inkjet layer (not shown) may be disposed between the global passivation layer and the overhang structures 110 and the encapsulation layers 116. The inkjet layer may include an acrylic material.

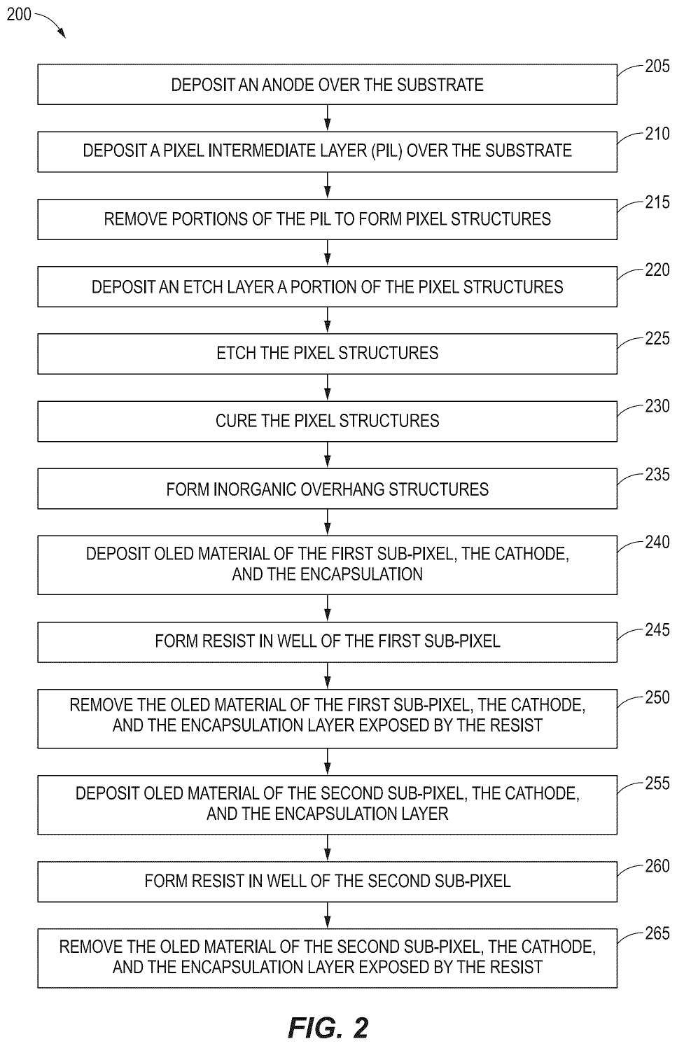

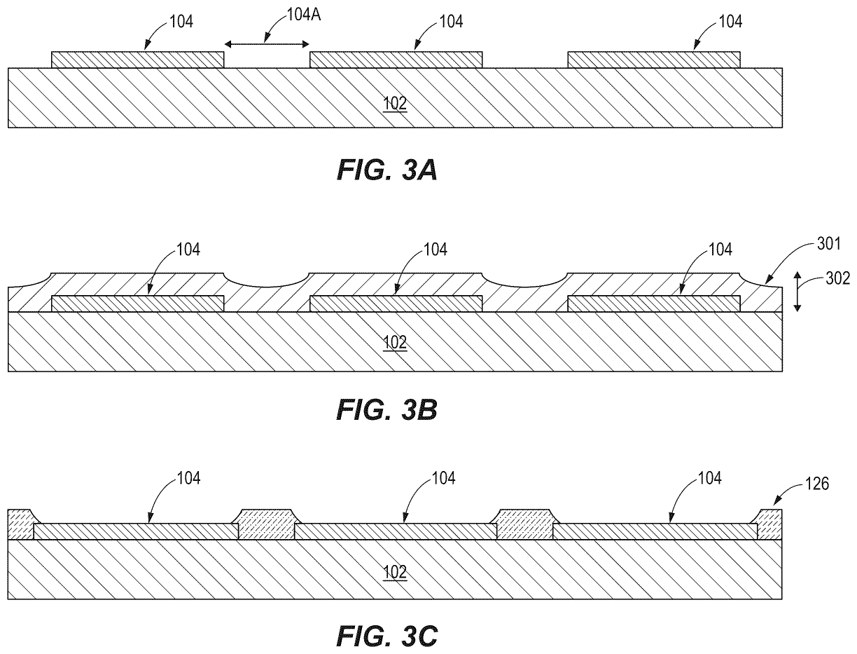

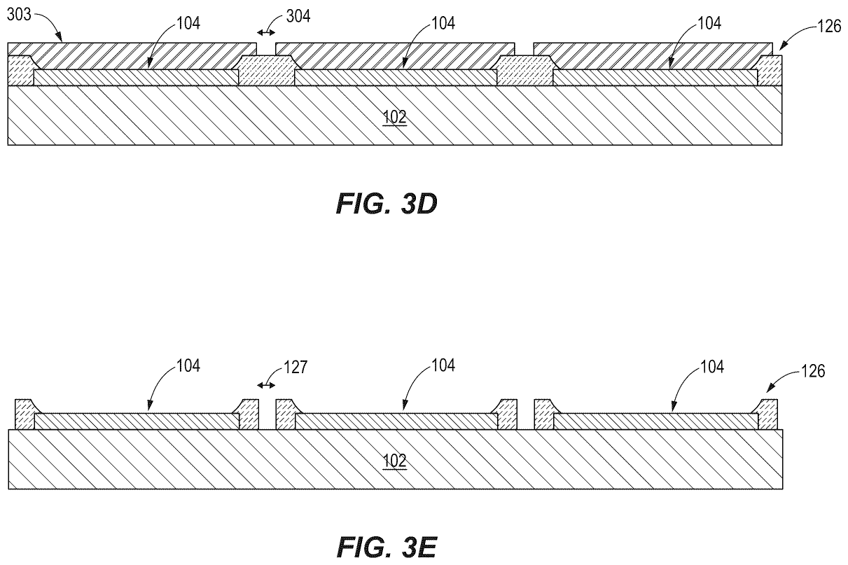

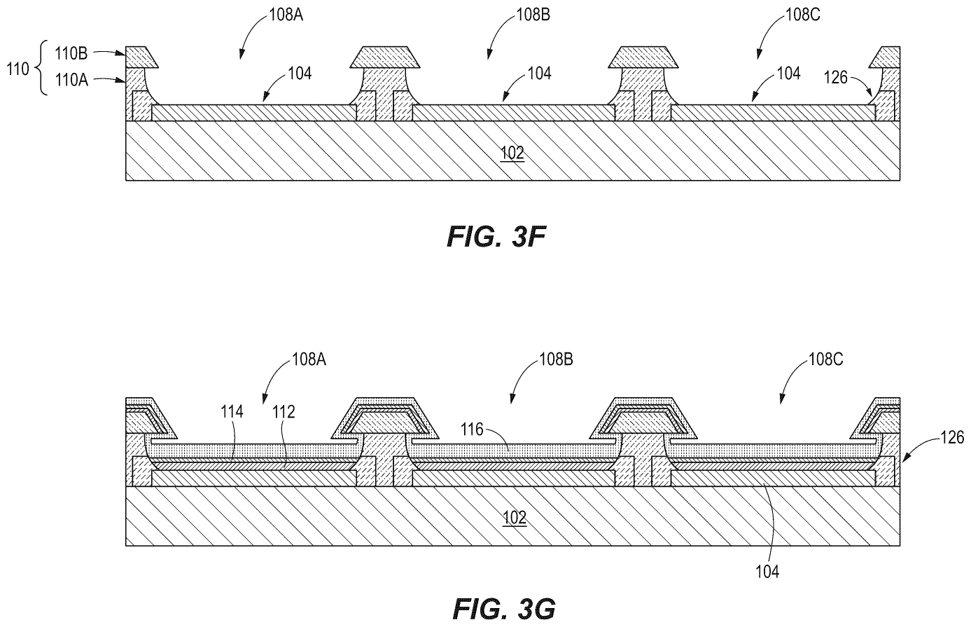

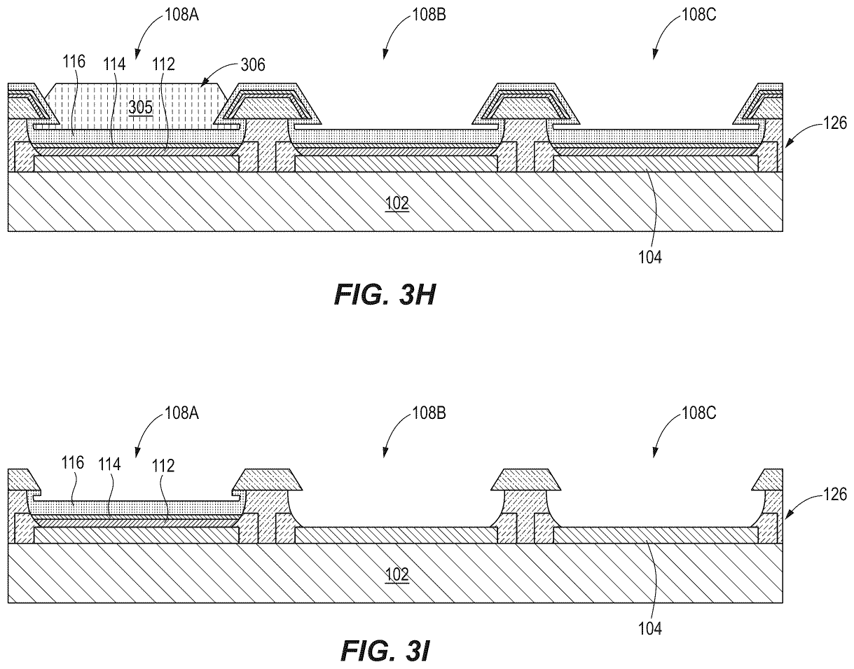

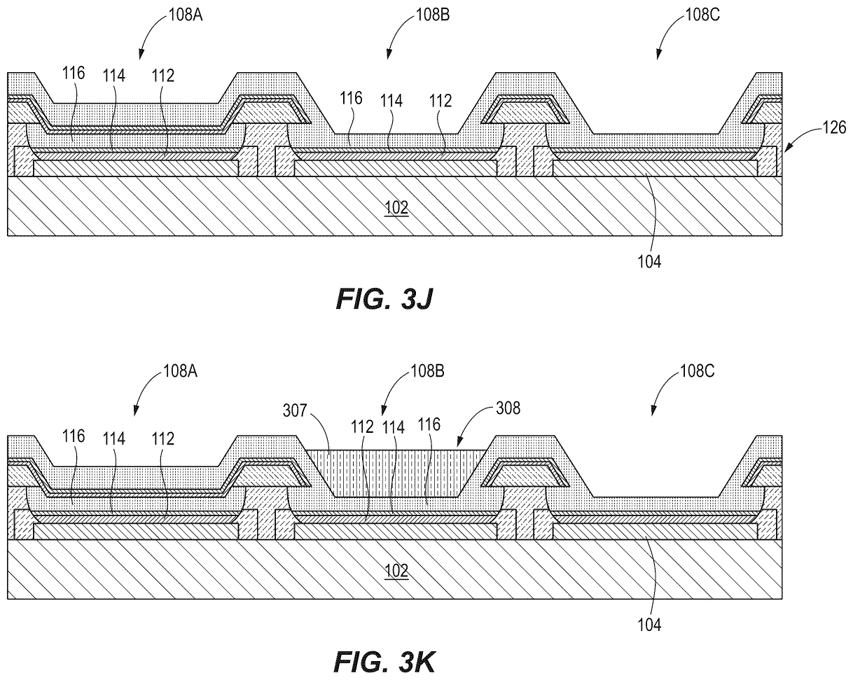

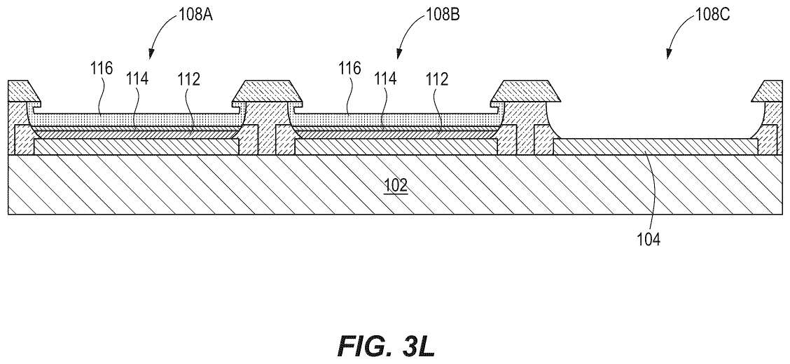

FIG. 2 is a flow diagram of a method 200 for forming a sub-pixel circuit 100 according to embodiments of the present disclosure. FIGS. 3A-3L are schematic, cross-sectional views of a substrate 102 during the method 200, according to embodiments of the present disclosure.

At operation 205, as shown in FIG. 3A, a metal-containing layer 104 is deposited over the substrate 102. The metal-containing layer 104 may be deposited on on a base layer (not shown). The base layer may be disposed on the substrate 102. The metal-containing layer 104 may be deposited using metal-organic decomposition (MOD) and/or physical vapor deposition (PVD). An anode gap 104A separates the metal-containing layer 104 from an adjacent metal-containing layer.

At operation 210, as shown in FIG. 3B, a pixel intermediate layer (PIL) 301 is deposited over the substrate 102. The PIL 301 may be deposited on the metal-containing layer 104 and/or on the base layer in the anode gap 104A. A height 302 from the substrate 102 to an upper surface of the PIL 301 is from about 100 nm to about 1000 nm, e.g., about 100 nm to about 900 nm, about 200 nm to about 900 nm, or about 300 nm to about 800 nm.

At operation 215, as shown in FIG. 3C, portions of the PIL 301 are removed. The PIL 301 may be removed by a wet etch or dry etch process. Operation 215 exposes the metal-containing layer 104 and forms PS 126. At operation 220, an etch layer 303 is deposited over and/or on the PS 126 and the metal-containing layer 104, as shown in FIG. 3D. In some embodiments, the etch layer 303 can include a photoresist. The etch layer 303 can be patterned such that an etch gap 304 exists between adjacent etch layers, thereby exposing an upper surface of the PS 126.

At operation 225, as shown in FIG. 3E, portions of the PS 126 are removed. The portions of the PS 126 may be removed by a wet etch or dry etch process. Operation 225 exposes the substrate 102 beneath the PS 126 by forming one or more outgassing holes 127. Operation 225 can include removing the etch layer 303 by stripping the etch layer 303 from the PS 126 and/or the metal-containing layer 104. At operation 230, the PS 126, the metal-containing layer 104, and the substrate 102 are cured. In some embodiments, the PS 126, the metal-containing layer 104, and the substrate may be cured according to a curing process. The curing process can include heating the PS 126, the metal-containing layer 104, and the substrate 102 at a temperature of about 100° C. to about 200° C. for about 10 minutes to about 30 minutes. Without being bound by theory, by curing the PS 126, the metal-containing layer 104, and the substrate 102 absorbed moisture may be released and/or expelled through the outgassing holes 127, thereby reducing peeling due to trapped moisture from forming between the substrate 102 and the metal-containing layer 104 and/or the substrate 102 and the PS 126, as well as reducing device degradation complications.

At operation 235, as shown in FIG. 3F, overhang structures 110 are formed over the PS 126. Forming the overhang structures 110 includes a lower portion 110A and an upper portion 110B being deposited over the substrate 102. The lower portion 110A is disposed over the PS 126. The lower portion 110A of the overhang structures 110 are disposed in the outgassing holes 127 such that the lower portion 110A fills the outgassing holes 127. Without being bound by theory, by disposing the lower portion 110A in the outgassing holes 127, moisture may be prevented from being introduced to the substrate 102, thereby reducing peeling and/or pixel degradation during the fabrication processes described herein. The upper portion 110B is disposed over the lower portion 110A. In some embodiments, an assistant cathode layer is disposed between the lower portion 110A and the PS 126. In some embodiments, a resist is disposed and patterned over the upper portion layer. To form the overhang structures 110 portions of the upper portion 110B and the lower portion 110A exposed by the pixel opening are removed via wet etch or dry etch processes.

At operation 240, as shown in FIG. 3G, the OLED material 112 of the first sub-pixel 108A, the cathode 114, and the encapsulation layer 116 are deposited. In embodiments including capping layers, the capping layers are deposited between the cathode 114 and the encapsulation layer 116. The capping layers may be deposited by evaporation deposition. In some embodiments, the OLED material 112 does not contact the lower portion 110A of the overhang structures 110, and the cathode 114 contacts the lower portion 110A of the overhang structures 110. In some embodiments, the OLED material 112 does not contact the lower portion 110A of the overhang structures 110 and the assistant cathode, and the cathode 114 contacts at least the assistant cathode. The encapsulation layer 116 is deposited over the cathode 114.

At operation 245, as shown in FIG. 3H, a first resist 305 is formed in a first well 306 of the first sub-pixel 108A. At operation 250, as shown in FIG. 3I, the encapsulation layer 116, the cathode 114, and the OLED material 112 exposed by the first resist 305 are removed. The encapsulation layer 116, the cathode 114, and the OLED material 112 exposed by the first resist 305 may be removed by dry and/or wet etch processes.

At operation 255, as shown in FIG. 3J, the OLED material 112 of the second sub-pixel 108B, the cathode 114, and the encapsulation layer 116 are deposited. In embodiments including capping layers, the capping layers are deposited between the cathode 114 and the encapsulation layer 116. The capping layers may be deposited by evaporation deposition. In some embodiments, the OLED material 112 does not contact the lower portion 110A of the overhang structures 110, and the cathode 114 contacts the lower portion 110A of the overhang structures 110. In some embodiments, the OLED material 112 does not contact the lower portion 110A of the overhang structures 110 and the assistant cathode, and the cathode 114 contacts at least the assistant cathode. The encapsulation layer 116 is deposited over the cathode 114.

At operation 260, as shown in FIG. 3K, a second resist 307 is formed in a second well 308 of the second sub-pixel 108B. At operation 265, as shown in FIG. 3L, the encapsulation layer 116, the cathode 114, and the OLED material 112 exposed by the second resist 307 are removed. The encapsulation layer 116, the cathode 114, and the OLED material 112 exposed by the second resist 307 may be removed by dry and/or wet etch processes. Operations 205-250 and/or 205-265 may be repeated for the third sub-pixel 108C and/or for one or more additional sub-pixels, e.g. a fourth sub-pixel and/or a fifth sub-pixel.

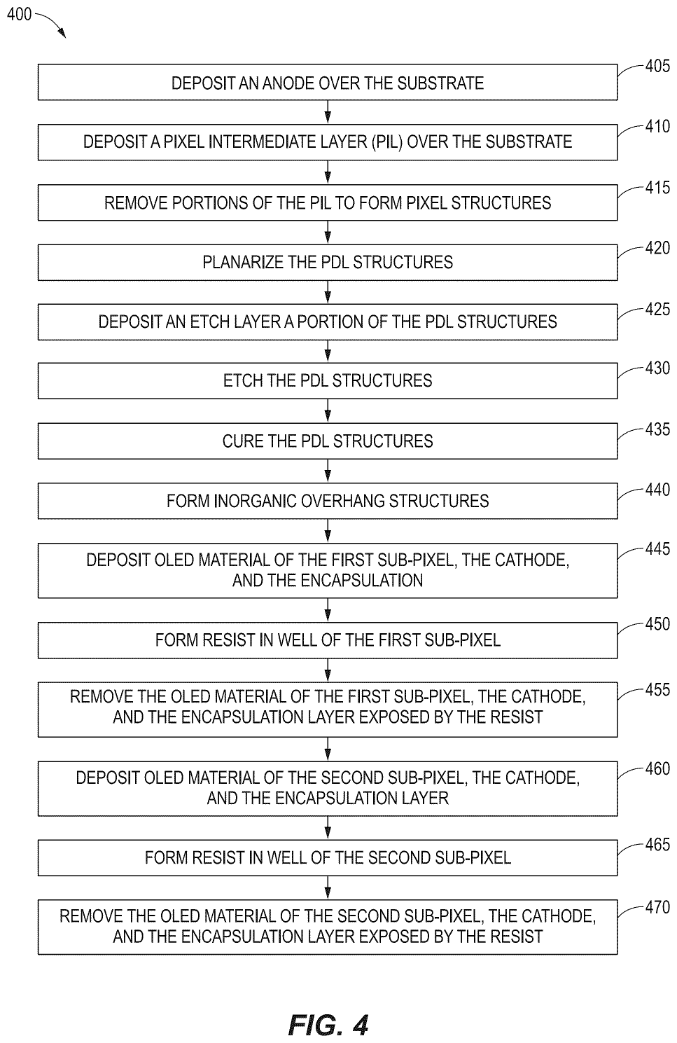

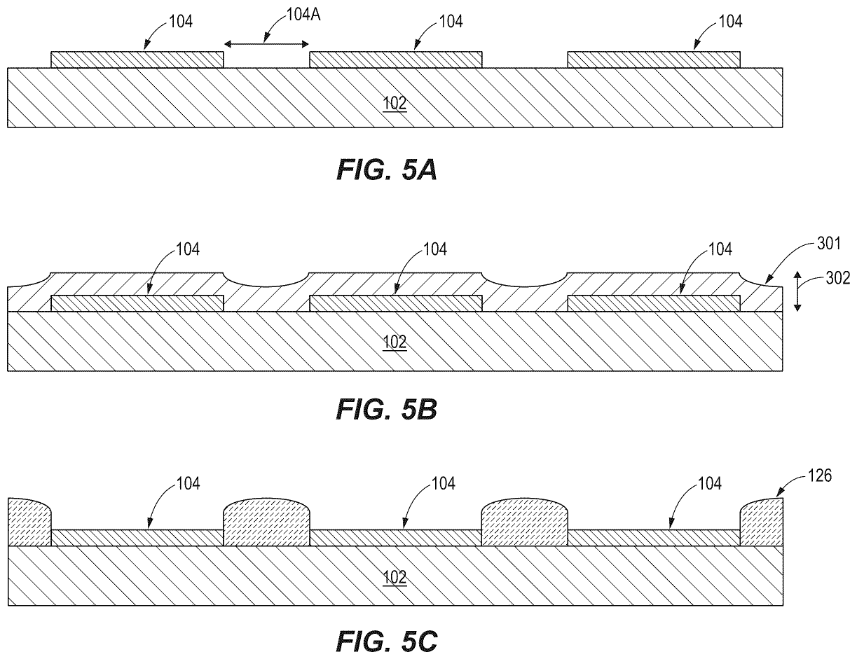

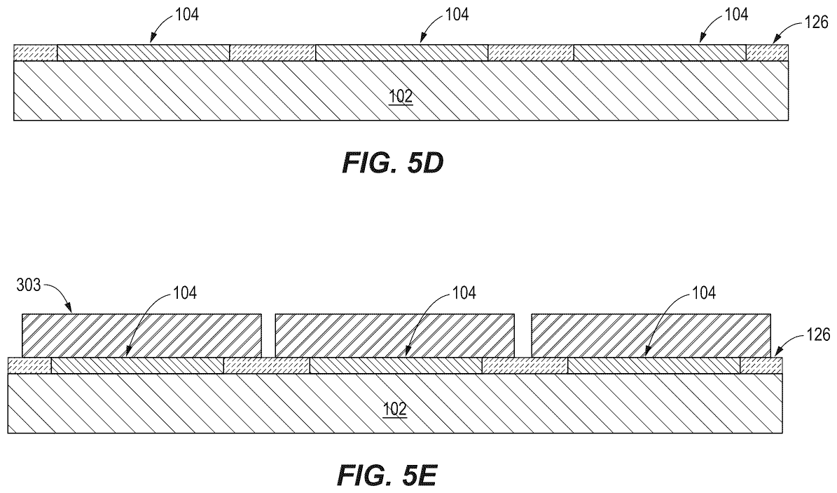

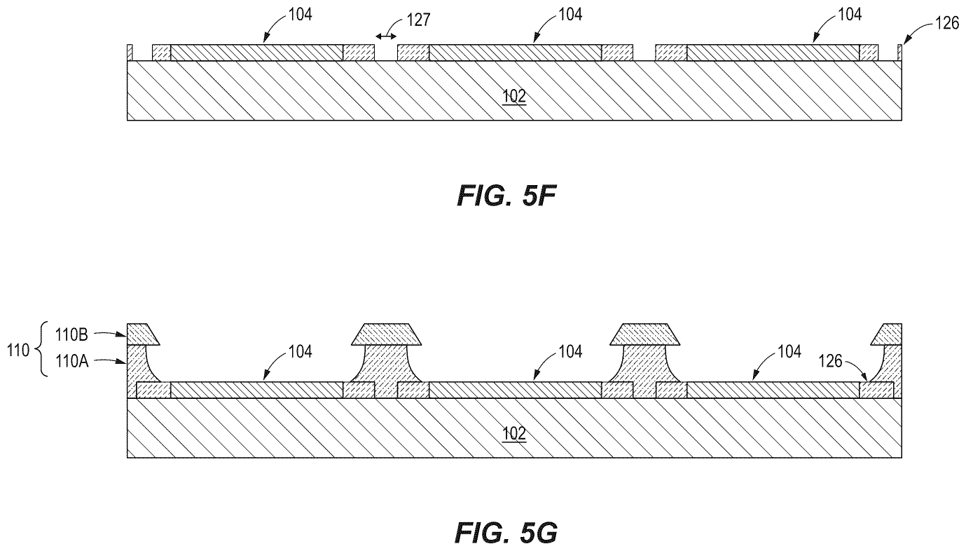

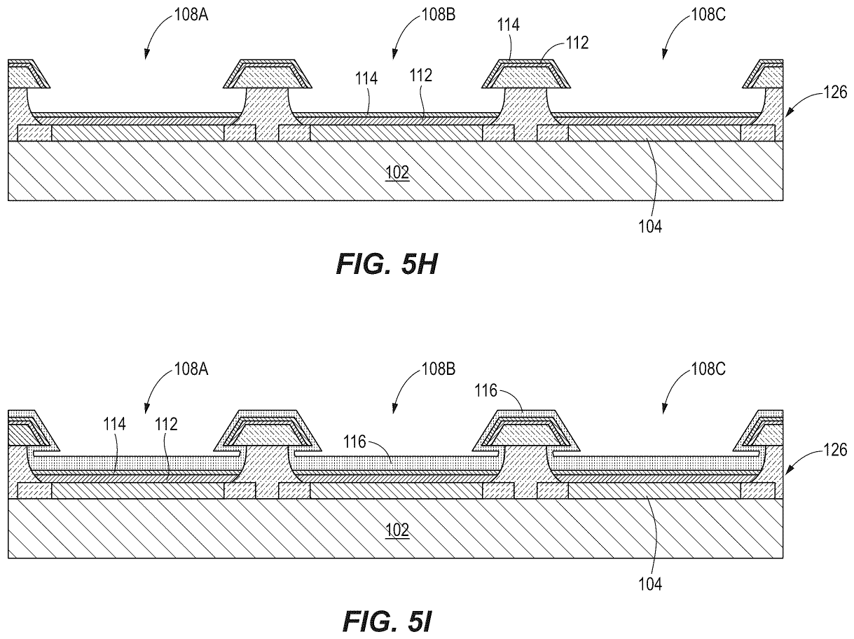

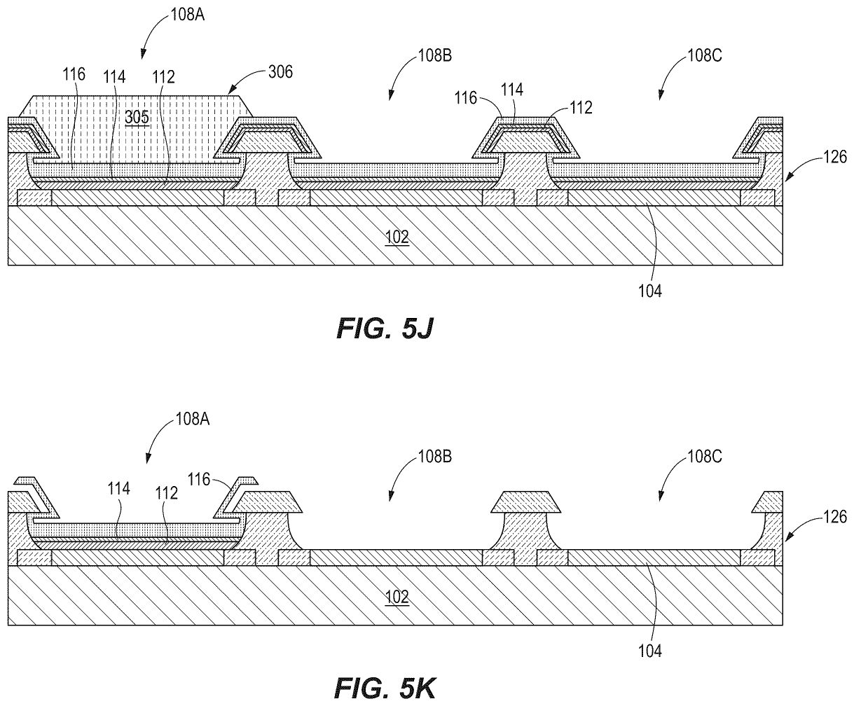

FIG. 4 is a flow diagram of a method 400 for forming a sub-pixel circuit 100 according to embodiments of the present disclosure. FIGS. 5A-5K are schematic, cross-sectional views of a substrate 102 during the method 400, according to embodiments of the present disclosure.

At operation 405, as shown in FIG. 5A, a metal-containing layer 104 is deposited over the substrate 102. The metal-containing layer 104 may be deposited on on a base layer (not shown). The base layer may be disposed on the substrate 102. The metal-containing layer 104 may be deposited using metal-organic decomposition (MOD) and/or physical vapor deposition (PVD). An anode gap 104A separates the metal-containing layer 104 from an adjacent metal-containing layer.

At operation 410, as shown in FIG. 5B, a pixel intermediate layer (PIL) 301 is deposited over the substrate 102. The PIL 301 may be deposited on the metal-containing layer 104 and/or on the base layer in the anode gap 104A. A height 302 from the substrate 102 to an upper surface of the PIL 301 is from about 100 nm to about 1000 nm, e.g., about 100 nm to about 900 nm, about 200 nm to about 900 nm, or about 300 nm to about 800 nm.

At operation 415, as shown in FIG. 5C, portions of the PIL 301 are removed. The PIL 301 may be removed by a wet etch or dry etch process. Operation 415 exposes the metal-containing layer 104 and forms PS 126.

At operation 420, as shown in FIG. 5D, the PS 126 are planarized. In some embodiments, the PS are planarized to form planarized pixel structures (PS). The upper surface of the PS 126 is aligned with the upper surface of the anode. The planarization process of the PS 126 may be performed using chemical-mechanical planarization (CMP). At operation 425, an etch layer 303 is deposited over and/or on the PS 126 and the metal-containing layer 104, as shown in FIG. 5E. In some embodiments, the etch layer 303 can include a photoresist. The etch layer 303 can be patterned such that an etch gap 304 exists between adjacent etch layers, thereby exposing an upper surface of the PS 126.

At operation 430, as shown in FIG. 5F, portions of the planarized PS are removed. The portions of the planarized PS may be removed by a wet etch or dry etch process. Operation 430 exposes the substrate 102 beneath the PS 126 by forming one or more outgassing holes 127. Operation 430 can include removing the etch layer 303 by stripping the etch layer 303 from the PS 126 and/or the metal-containing layer 104. At operation 435, the PS 126, the metal-containing layer 104, and the substrate 102 are cured. In some embodiments, the PS 126, the metal-containing layer 104, and the substrate may be cured according to a curing process. The curing process can include heating the PS 126, the metal-containing layer 104, and the substrate 102 at a temperature of about 100° C. to about 200° C. for about 10 minutes to about 30 minutes. Without being bound by theory, by curing the PS 126, the metal-containing layer 104, and the substrate 102 absorbed moisture may be released and/or expelled through the outgassing holes 127, thereby reducing peeling due to trapped moisture from forming between the substrate 102 and the metal-containing layer 104 and/or the substrate 102 and the PS 126, as well as reducing device degradation complications.

At operation 440, as shown in FIG. 5G, overhang structures 110 are formed over the PS 126. Forming the overhang structures 110 includes a lower portion 110A and an upper portion 110B being deposited over the substrate 102. The lower portion 110A is disposed over the PS 126. The lower portion 110A of the overhang structures 110 are disposed in the outgassing holes 127. Without being bound by theory, by disposing the lower portion 110A in the outgassing holes 127, moisture may be prevented from being introduced to the substrate 102, thereby reducing peeling and/or pixel degradation during the fabrication processes described herein. The upper portion 110B is disposed over the lower portion 110A. In some embodiments, an assistant cathode layer is disposed between the lower portion 110A and the PS 126. In some embodiments, a resist is disposed and patterned over the upper portion layer. To form the overhang structures 110 portions of the upper portion 110B and the lower portion 110A exposed by the pixel opening are removed via wet etch or dry etch processes.

At operation 445, the OLED material 112 of the first sub-pixel 108A, the cathode 114, and the encapsulation layer 116 are deposited, as shown in FIG. 5H and FIG. 5I. In embodiments including capping layers, the capping layers are deposited between the cathode 114 and the encapsulation layer 116. The capping layers may be deposited by evaporation deposition. In some embodiments, the OLED material 112 does not contact the lower portion 110A of the overhang structures 110, and the cathode 114 contacts the lower portion 110A of the overhang structures 110. In some embodiments, the OLED material 112 does not contact the lower portion 110A of the overhang structures 110 and the assistant cathode, and the cathode 114 contacts at least the assistant cathode. In some embodiments, the encapsulation layer 116 is deposited over the cathode 114 the lower portion 110A and/or the upper portion 110B.

At operation 450, as shown in FIG. 5J, a first resist 305 is formed in a first well 306 of the first sub-pixel 108A. At operation 455, as shown in FIG. 5K, the encapsulation layer 116, the cathode 114, and the OLED material 112 exposed by the first resist 305 are removed. The encapsulation layer 116, the cathode 114, and the OLED material 112 exposed by the first resist 305 may be removed by wet etch processes.

At operation 460, the OLED material 112 of the second sub-pixel 108B, the cathode 114, and the encapsulation layer 116 are deposited. In embodiments including capping layers, the capping layers are deposited between the cathode 114 and the encapsulation layer 116. The capping layers may be deposited by evaporation deposition. In some embodiments, the OLED material 112 does not contact the lower portion 110A of the overhang structures 110, and the cathode 114 contacts the lower portion 110A of the overhang structures 110. In some embodiments, the OLED material 112 does not contact the lower portion 110A of the overhang structures 110 and the assistant cathode, and the cathode 114 contacts at least the assistant cathode. In some embodiments, the encapsulation layer 116 is deposited over the cathode 114 the lower portion 110A and/or the upper portion 110B.

At operation 465, a second resist is formed in a second well of the second sub-pixel 108B. At operation 470, the encapsulation layer 116, the cathode 114, and the OLED material 112 exposed by the second resist are removed. The encapsulation layer 116, the cathode 114, and the OLED material 112 exposed by the second resist may be removed by dry and/or wet etch processes. Operations 405-450 and/or 405-470 may be repeated for the third sub-pixel 108C and/or for one or more additional sub-pixels, e.g. a fourth sub-pixel and/or a fifth sub-pixel.

Overall, the sub-pixel circuits of the present disclosure can include pixel structures having one or more outgassing holes disposed over a substrate, thereby allowing moisture that is absorbed during fabrication processes to be released. The release of the absorbed moisture prevents pixel degradation and/or peeling, by reducing trapped moisture between the substrate and the anodes and/or pixel defining layers during sub-pixel circuit fabrication.

While the foregoing is directed to embodiments of the present disclosure, other and further embodiments of the disclosure may be devised without departing from the basic scope thereof, and the scope thereof is determined by the claims that follow.

What is claimed is:

1. A sub-pixel, comprising:
a plurality of pixel structures separating a plurality of anodes, the plurality of pixel structures disposed over a substrate, each pixel structure of the plurality of pixel structures comprising an outgassing hole;
a plurality of overhang structures disposed over the plurality of pixel structures, each overhang structure of the plurality of overhang structures comprising an upper portion disposed over a lower portion, wherein a bottom surface of the upper portion extends laterally past an upper surface of the lower portion, wherein the lower portion fills the outgassing hole;
an organic light emitting diode (OLED) material disposed over an upper surface of the plurality of anodes and an upper surface of the plurality of pixel structures; and
a cathode disposed over the OLED material and the upper surface of the plurality of pixel structures.

2. The sub-pixel of claim 1, wherein the upper surface of the plurality of pixel structures is aligned with the upper surface of the plurality of anodes.

3. The sub-pixel of claim 1, wherein the upper surface of the plurality of pixel structures extends above the upper surface of the plurality of anodes.

4. The sub-pixel of claim 1, wherein the outgassing hole comprises a diameter of about 0.1 μm to about 10 μm.

5. The sub-pixel of claim 1, wherein the plurality of pixel structures comprises silicon nitride (Si₃N₄), silicon oxide (SiO₂), or silicon oxynitride (Si₂N₂O).

6. The sub-pixel of claim 1, wherein the lower portion comprises:
an inorganic silicon-containing material comprising one or more of amorphous silicon (a-Si), silicon nitride (Si₃N₄), silicon oxide (SiO₂), or silicon oxynitride (Si₂N₂O); or a conductive material comprising one or more of a transparent conductive oxide, aluminum (Al), aluminum neodymium (AlNd), molybdenum (Mo), molybdenum tungsten (MoW), copper (Cu).

7. The sub-pixel of claim 1, wherein the upper portion comprises one or more of a transparent conductive oxide, copper (Cu), chromium (Cr), aluminum (Al), aluminum neodymium (AlNd), molybdenum (Mo), molybdenum tungsten (MoW), or titanium (Ti).

8. A device, comprising:
a plurality of sub-pixels comprising at least a first sub-pixel, a second sub-pixel, and a third sub-pixel, the first sub-pixel, the second sub-pixel, and the third sub-pixel each comprising:
a plurality of pixel structures, the plurality of pixel structures separating a plurality of anodes, each pixel structure of the plurality of pixel structures comprising an outgassing hole;
overhang structures disposed over the plurality of pixel structures, each overhang structure comprising an upper portion disposed over a lower portion, wherein a bottom surface of the upper portion extends laterally past an upper surface of the lower portion, wherein the lower portion fills the outgassing hole;
an organic light emitting diode (OLED) material disposed over an upper surface of the plurality of anodes and an upper surface of the plurality of pixel structures, the OLED material of the first sub-pixel emits a first color, the OLED material of the second sub-pixel emits a second color, and the OLED material of the third sub-pixel emits a third color; and
a cathode disposed over the OLED material and the upper surface of the plurality of pixel structures.

9. The device of claim 8, wherein the upper surface of the plurality of pixel structures is aligned with the upper surface of the plurality of anodes.

10. The device of claim 8, wherein the upper surface of the plurality of pixel structures extends above the upper surface of the plurality of anodes.

11. The device of claim 8, wherein the outgassing hole comprises a diameter of about 0.1 μm to about 10 μm.

12. The device of claim 8, wherein the plurality of pixel structures comprises silicon nitride (Si₃N₄), silicon oxide (SiO₂), or silicon oxynitride (Si₂N₂O).

13. The device of claim 8, wherein the lower portion comprises:
an inorganic silicon-containing material comprising one or more of amorphous silicon (a-Si), silicon nitride (Si₃N₄), silicon oxide (SiO₂), or silicon oxynitride (Si₂N₂O); or a conductive material comprising one or more of a transparent conductive oxide, aluminum (Al), aluminum neodymium (AlNd), molybdenum (Mo), molybdenum tungsten (MoW), copper (Cu).

14. The device of claim 8, wherein the upper portion comprises one or more of a transparent conductive oxide, copper (Cu), chromium (Cr), aluminum (Al), aluminum neodymium (AlNd), molybdenum (Mo), molybdenum tungsten (MoW), or titanium (Ti).

15. A method of forming a device, comprising:
depositing an anode and a pixel intermediate layer (PIL) over a substrate;
removing portions of the PIL to form a plurality of pixel structures;
depositing an etch layer over a portion of the plurality of pixel structures;
etching the plurality of pixel structures to form an outgassing hole in the plurality of pixel structures, the outgassing hole exposing a surface of the substrate;
curing the plurality of pixel structures, the anode, and the substrate;
forming overhang structures over the plurality of pixel structures, the overhang structures comprising an upper portion disposed over a lower portion;
depositing an organic light emitting diode (OLED) material, a cathode, and an encapsulation layer;
depositing and patterning a resist in a first sub-pixel;
removing a portion of the OLED material, a portion of the cathode, and a portion of the encapsulation layer; and
removing the resist.

16. The method of claim 15, further comprising planarizing the plurality of pixel structures to form a plurality of planarized pixel structures, wherein the plurality of planarized pixel structures comprise an upper surface aligned with the upper surface of the anode.

17. The method of claim 15, wherein curing the plurality of pixel structures, the anode, and the substrate comprises heating the plurality of pixel structures, the anode, and the substrate at a temperature of about 100°° C. to about 200° C.

18. The method of claim 17, wherein heating the plurality of pixel structures, the anode, and the substrate comprises heating for about 10 minutes to about 30 minutes.

19. The method of claim 15, wherein forming the outgassing hole comprises forming a diameter of about 0.1 μm to about 10 μm.

20. The method of claim 15, further comprising disposing the lower portion in the outgassing hole in the plurality of pixel structures.
